(19) United States
(12) Patent Application Publication
(10) Pub. No.: US 2016/0284522 A1
(43) Pub. Date: Sep. 29, 2016

(54) UPPER ELECTRODE, EDGE RING, AND PLASMA PROCESSING APPARATUS

(71) Applicant: KABUSHIKI KAISHA TOSHIBA, Minato-ku (JP)

(72) Inventors: Hideo ETO, Yokkaichi (JP); Masanori Abe, Nomi (JP); Makoto Saito, Nomi (JP)

(73) Assignee: KABUSHIKI KAISHA TOSHIBA, Minato-ku (JP)

(21) Appl. No.: 14/800,938

(22) Filed: Jul. 16, 2015

(30) Foreign Application Priority Data
Mar. 25, 2015 (JP) 2015-063151

(51) Int. Cl. H01J 37/32; C23C 16/455; C23C 16/458; C23C 16/50

(52) U.S. Cl. CPC H01J 37/32532; C23C 16/50; H01J 37/3244; C23C 16/45565; C23C 16/458

(57) ABSTRACT

According to one embodiment, an upper electrode to be arranged opposite to a lower electrode and serving as a shower head in a plasma processing apparatus of a parallel-plate type is provided. The upper electrode includes a concave portion provided on an outer peripheral side of a processing object opposing region configured to face a mounting region for a processing object to be placed on the lower electrode.

### CROSS-REFERENCE TO RELATED APPLICATIONS

This application is based upon and claims the benefit of priority from Japanese Patent Application No. 2015-63151, filed on Mar. 25, 2015; the entire contents of which are incorporated herein by reference.

### FIELD

Embodiments described herein relate generally to an upper electrode, an edge ring, and a plasma processing apparatus.

### BACKGROUND

As an RIE (Reactive Ion Etching) apparatus, there is known an apparatus having a parallel-plate type structure that includes a lower electrode and an upper electrode arranged in parallel with each other, in which the lower electrode is configured to hold a wafer and the upper electrode is formed with a plurality of gas passages for supplying an etching gas. In the RIE apparatus of the parallel-plate type, the upper electrode is grounded, and the lower electrode is supplied with a radio frequency (RF) power, so that a gas supplied into a space between the upper electrode and the lower electrode is turned into plasma.

Near the outer peripheral area around the wafer, the plasma can easily spread outward therefrom. In consideration of this, that position of the upper electrode which opposes the outer peripheral area around the wafer is provided with a convex portion protruding toward the peripheral area. Consequently, the plasma can be confined within a region where the wafer is placed, and the etching efficiency is improved near the peripheral edge of the wafer.

However, electric lines of force near the center of the wafer are almost perpendicular to the wafer mounting surface of the lower electrode, but electric lines of force near the peripheral edge of the wafer are inclined by a certain angle from the direction perpendicular to the wafer mounting surface. Consequently, the processed shape obtained by etching near the peripheral edge of the wafer may end up being inclined in accordance with the directions of the electric lines of force.

### BRIEF DESCRIPTION OF THE DRAWINGS

FIG. 1 is a sectional view schematically showing an example of a configuration of a plasma processing apparatus according to a first embodiment;

FIG. 2 is a partial sectional view showing a structure including an upper electrode and a lower electrode, according to the first embodiment;

FIG. 3 is a sectional view showing another example of a structure of an upper electrode according to the first embodiment;

FIG. 4 is a partial sectional view showing a structure including an upper electrode and a lower electrode in a general plasma processing apparatus;

FIG. 5 is a partial sectional view schematically showing an example of a structure including an upper electrode and a lower electrode in a plasma processing apparatus according to a second embodiment;

FIG. 6 is a partial sectional view schematically showing another example of a structure including an upper electrode and a lower electrode in a plasma processing apparatus according to the second embodiment; and

FIG. 7 is a partial sectional view schematically showing an example of a structure including an upper electrode and a lower electrode in a plasma processing apparatus according to a third embodiment.

### DETAILED DESCRIPTION

In general, according to one embodiment, an upper electrode to be arranged opposite to a lower electrode and serving as a shower head in a plasma processing apparatus of a parallel-plate type is provided. The upper electrode includes a concave portion provided on an outer peripheral side of a processing object opposing region configured to face a mounting region for a processing object to be placed on the lower electrode.

Exemplary embodiments of an upper electrode, an edge ring, and a plasma processing apparatus will be explained below in detail with reference to the accompanying drawings. The present invention is not limited to the following embodiments.

### First Embodiment

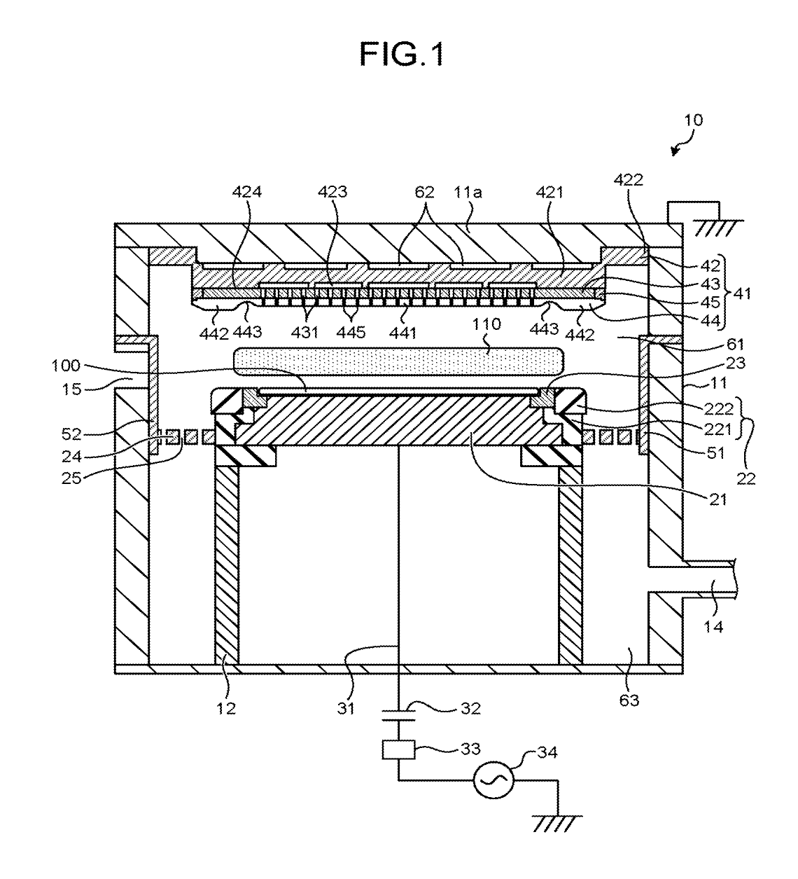

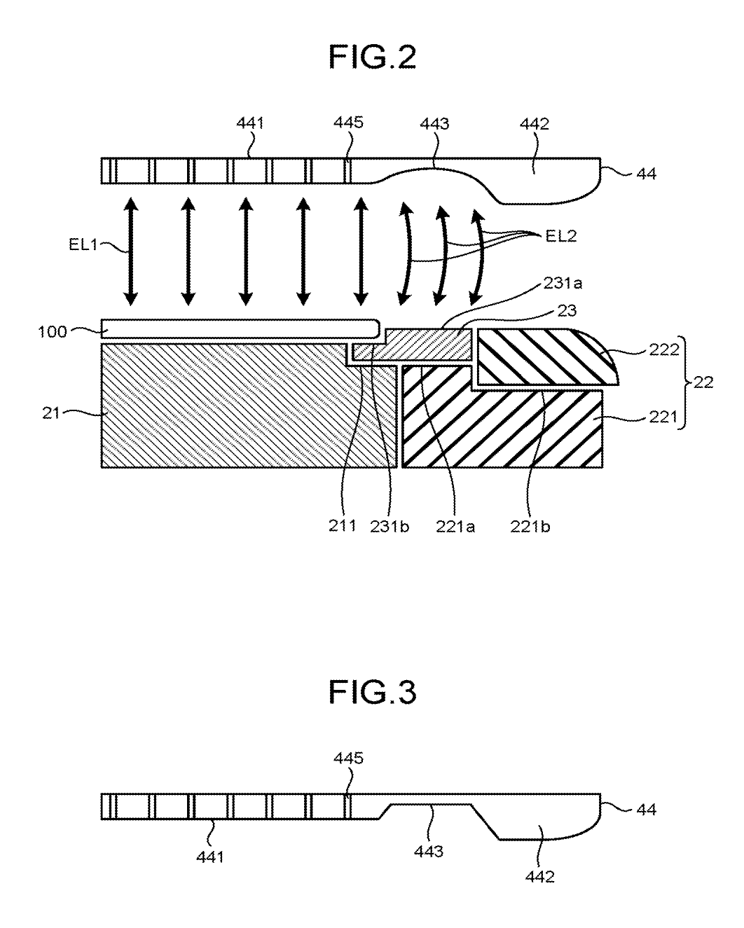

FIG. 1 is a sectional view schematically showing an example of a configuration of a plasma processing apparatus according to a first embodiment. FIG. 2 is a partial sectional view showing a structure including an upper electrode and a lower electrode according to the first embodiment. FIG. 3 is a sectional view showing another example of a structure of an upper electrode according to the first embodiment. In this embodiment, the plasma processing apparatus 10 is exemplified by an RIE apparatus.

The plasma processing apparatus 10 includes a chamber 11 made of aluminum, for example, and configured in an airtight state. A support table 21 serving as a processing object support member is provided inside the chamber 11, and is configured to support a wafer 100 treated as a processing object in a horizontal state and to function as a lower electrode. The support table 21 is equipped with a holding mechanism (not shown), such as an electrostatic chuck mechanism for attracting and holding the wafer 100 by an electrostatic force. An insulator ring 22 made of an insulating material is provided to cover a side surface and peripheral edge of a bottom surface of the support table 21. An edge ring 23 made of, e.g., silicon, SIC, or quartz is provided on the outer peripheral area around the upper side of the support table 21 covered with the insulator ring 22. This edge ring 23 a member provided to adjust an electric field formed during etching of the wafer 100, so that the electric field is not deflected relative to the vertical direction (the direction perpendicular to the wafer surface) at the peripheral edge of the wafer 100.

Further, the support table 21 is supported through the insulator ring 22 on a cylindrical support part 12 protruding vertically upward from the bottom wall of the chamber 11 near the center. A baffle plate 24 is arranged between the insulator ring 22 and a sidewall of the chamber 11. The baffle plate 24 includes a plurality of gas exhaust holes 25 penetrating the plate in a thickness direction. Further, the support table 21 is connected to a feeder line 31 for supplying an RF power, and this feeder line 31 is connected to a blocking capacitor 32, a matching box 33, and an RF power supply 34. During a plasma process, the RF power supply 34 supplies an RF power having a predetermined frequency to the support table 21.

A shower head 41 is arranged opposite to the upper surface of the support table 21 functioning as a lower electrode. The upper surface of the support table 21 and the lower surface of the shower head 41 are separated from each other by a predetermined distance. As described later, the shower head 41 includes an upper electrode 44. The shower head 41 is fixed to a top plate 11a, which constitutes an upper part of the chamber 11, by fixing members (not shown). The top plate 11a is set to the ground potential during the plasma process. In this way, the shower head 41 and the support table 21 constitute a pair of parallel-plate electrode.

The chamber 11 includes a gas supply port (not shown) provided near an upper side. The gas supply port is connected to a gas supply unit (not shown) through a piping line. During the plasma process, the gas supply unit supplies a process gas through the gas supply port into the chamber 11.

The chamber 11 includes a gas exhaust port 14 provided below the support table 21 and the baffle plate 24. The gas exhaust port 14 is connected to a vacuum pump (not shown) through a piping line. During the plasma process, the vacuum hump sets the inside of the chamber 11 to a predetermined vacuum level.

Further, the sidewall of the chamber 11 within a region partitioned between the baffle plate 24 and the shower head 41 is covered with a deposition shield 51 that prevents a reaction product generated during the plasma process from being deposited onto the sidewall of the chamber 11. Further, the chamber 11 includes an opening 15 for loading and unloading the wafer 100, formed on the sidewall at a predetermined position, and a shutter 52 is provided at that portion of the deposition shield 51 which corresponds to this opening 15. The shutter 52 serves to separate an outside and the inside of the chamber 11, and it is opened to connect the opening 15 to the inside of the chamber 11 when the wafer 100 is loaded and unloaded.

The inside of the plasma processing apparatus 10 having this configuration can be considered as being divided into a plasma processing room 61, a gas supply room 62, and a gas exhaust room 63. The plasma processing room 61 is formed of a region partitioned by the support table 21, the baffle plate 24, and the shower head 41 inside the chamber 11. The gas supply room 62 is formed of an upper region inside the chamber 11, which is partitioned by the shower head 41. The gas exhaust room 63 is formed of a lower region inside the chamber 11, which is partitioned by the support part 12 and the baffle plate 24.

Next, with reference to FIGS. 1 and 2, an explanation will be given of a structure around the support table 21. The insulator ring 22 includes a lower insulator ring 221 having a ring shape and an upper insulator ring 222 having a ring shape. The lower insulator ring 221 supports the edge ring 23, and is arranged around the support table 21. The upper insulator ring 222 is placed on the peripheral edge of the lower insulator ring 221.

The lower insulator ring 221 is made of quartz, for example. The lower insulator ring 221 includes, on its upper surface side, an edge ring mounting portion 221a for placing the edge ring 23 thereon, and an upper insulator ring mounting portion 221b for placing the upper insulator ring 222 thereon. The upper surface of each of the edge ring mounting portion 221a and the upper insulator ring mounting portion 221b is flat. In the example shown in FIG. 2, the upper surface of the upper insulator ring mounting portion 221b is lower than the upper surface of the edge ring mounting portion 221a, and a stepwise is formed between these portions.

The edge ring 23 is placed on the edge ring mounting portion 221a. The upper insulator ring 222 is placed on the upper insulator ring mounting portion 221b. In other words, the upper insulator ring 222 is placed to fit in a step formed on the lower insulator ring 221. In this way, the upper insulator ring 222 is fitted in the step formed on the lower insulator ring 221, by which the upper insulator ring 222 is suppressed from making an unintended displacement in directions on a horizontal plane. The upper insulator ring 222 may be simply placed on the lower insulator ring 221, or may be fixed to the lower insulator ring 221 by fixing members. The upper insulator ring 222 is formed of a sintered body of silicon oxide or yttria.

The width of the upper insulator ring 222 is set slightly larger than the width of the upper insulator ring mounting portion 221b of the lower insulator ring 221. Thus, the side surface portion of the upper insulator ring 222 on an outer peripheral side protrudes outward from the side surface portion of the lower insulator ring 22 outer peripheral side. During the plasma process, this arrangement can suppress ions or radicals from flying onto the side surface of the lower insulator ring 221.

The support table 21 also includes a step portion 211 at the peripheral edge of the upper surface, such that the surface forming the step portion 211 has the same height as the upper surface of the edge ring mounting portion 221a of the lower insulator ring 221. Here, the edge ring 23 supported by the step portion 211 of the support table 21 and by the edge ring mounting portion 221a of the lower insulator ring 221. Further, the edge ring 23 is fixed by the side surface of the upper insulator ring 222 on the inner peripheral side and by the side surface of the support table 21 forming the step portion 211, so that it is suppressed from moving in the radial direction. In other words, the edge ring 23 is designed to be placed on the edge ring mounting portion 221a of the lower insulator ring 221 and on the step portion 211 of the support table 21, so that the edge ring 23 does not protrude from the outer peripheral side of the edge ring mounting portion 221a.

The upper surface portion 231a of the edge ring 23 has almost the same height as an upper surface of the upper insulator ring 222. Further, an upper surface of the edge ring 23 on the inner peripheral side is provided with a wafer mounting portion 231b for supporting the peripheral edge of the wafer 100. An upper surface of the wafer mounting portion 231b is lower than the upper surface portion 231a, and has the same height as the upper surface of the support table 21. Each of the upper surface portion 231a and the wafer mounting portion 231b is flat. The lower surface of the edge ring 23 is flat, so that it is stably supported on the edge ring mounting portion 221a of the lower insulator ring 221 and on the step portion 211 of the support table 21.

Next, with reference to FIGS. 1 and 2, an explanation will be given of a structure of the shower head 41. The shower head 41 includes a cooling plate 42, a back plate 43, an upper electrode 44, and a guard ring 45.

The cooling plate 42 has a structure to circulate a coolant, such as water with a predetermined temperature, supplied from outside, so that the temperature of the back plate 43 and the upper electrode 44 is set to the predetermined temperature during the plasma process. The cooling plate 42 is made of stainless steel, for example. The cooling plate 42 includes an electrode holding portion 421 and a support part 422. The electrode holding portion 421 is a portion that holds a structure body composed of the back plate 43, the upper electrode 44, and the guard ring 45. The support part 422 is fixed to the top plate 11a of the chamber 11.

The electrode holding portion 421 protrudes from the support part 422 toward the support table 21. The electrode holding portion 421 includes grooves 423 formed in the region opposing the wafer mounting region. When the back plate 43 is arranged, the grooves 423 serve as plenum room. The grooves 423 are connected to the gas supply room 62 through gas passages (not shown). The electrode holding portion 421 includes a flat portion 424 arranged around the region provided with the grooves 423.

The back plate 43 is formed of a circular disk-shaped member having an almost uniform thickness, for example, and is provided on the electrode holding portion 421 of the cooling plate 42 on the support table 21 side. The back plate 43 is made of a material excellent in thermal conductivity and electrical conductivity, so that the upper electrode 44 is cooled by the cooling plate 42, and that the upper electrode 44 is set to the ground potential. The back plate 43 is made of aluminum or aluminum alloy, for example.

The back plate 43 includes gas passages 431 that penetrate the back plate 43 in a thickness direction and are arranged in a two-dimensional state within a region opposing the mounting region for the wafer 100. The back plate 43 is fixed to the cooling plate 42 by fixing members (not shown), such that the peripheral edge portion of the region provided with the gas passages 431 is overlapped with the flat portion 424 of the cooling plate 42. The contact of the flat portion 424 of the cooling plate 42 with the back plate 43 serves to perform thermal and electrical conduction between the cooling plate 42 and the back plate 43.

The upper electrode 44 is arranged in contact with the back plate 43 on the support table 21 side of the back plate 43, and is fixed to the back plate 43 by fixing members (not shown). The upper electrode 44 is made of silicon or the like. The upper electrode 44 is formed of a circular disk-shaped member that is flat on the back plate 43 side and includes a gas passage arrangement portion 441, a convex portion 442, and a concave portion 443 on the support table 21 side.

The gas passage arrangement portion 441 is that region of the circular disk-shaped member which opposes the mounting region for the wafer 100, and has a constant thickness. The gas passage arrangement portion 441 includes gas passages 445 that penetrate the circular disk-shaped member in a thickness direction and are arranged in a two-dimensional state. The gas passages 445 are arranged to positionally coincide with the gas passages 431 of the back plate 43, in a state where the upper electrode 44 is fixed to the back plate 43, after the upper electrode 44 is positioned relative to the back plate 43. In the example shown here, the diameter of the gas passages 445 of the upper electrode 44 is set smaller than the diameter of the gas passages 431 of the back plate 43.

The convex portion 442 is arranged outside the gas passage arrangement portion 441 of the circular disk-shaped member, and has a larger thickness than the gas passage arrangement portion 441. A maximum thickness of the convex portion 442 may be set to about 1.5 to 2 times the thickness of the gas passage arrangement portion 441, for example. The convex portion 442 has a function of suppressing plasma from spreading outward from the peripheral edge of the wafer 100 during the plasma process. Further, in order to reduce disturbance of the electric field at the peripheral edge of the upper electrode 44, the convex portion 442 is preferably formed in a Rogowski shape having a structure in which the thickness is gradually reduced in a direction toward the outer peripheral area. The convex portion 442 is arranged at a position facing the upper insulator ring 222.

The concave portion 443 is arranged on the outer peripheral side of the gas passage arrangement portion 441 and on the inner peripheral she of the convex portion 442. The thickness of the concave portion 443 is set smaller than the gas passage arrangement portion 441. A minimum thickness of the concave portion 443 may be set to about 0.8 to 0.95 times the thickness of the gas passage arrangement portion 441, for example. With the concave portion 443 thus provided, the distance between the upper electrode 44 and the wafer 100 (or the edge ring 23) becomes larger at the peripheral edge of the mounting region for the wafer 100, and the curves of electric lines of force can be thereby relaxed. The concave portion 443 is arranged at a position facing the edge ring 23.

The guard ring 45 is provided at that region of the outer peripheral area around the back plate 43 which is sandwiched between the cooling plate 4 and the upper electrode 44.

Further, ft the outer peripheral area around a structure body composed of the electrode holding portion 421 of the cooling plate 42, the back plate 43, and the upper electrode 44 overlapped with each other, a confinement ring (not for confining plasma is provided at a position distant by a predetermined distance therefrom. The confinement ring has a ring shape with an inner diameter slightly larger than the diameter of the upper electrode 44 (or the electrode holding portion 421).

The concave portion 443 may be formed in a curved shape as shown in FIGS. 1 and 2, or may be formed as shown in FIG. 3 in which the profile lines of a side and bottom surfaces of the concave portion 443 are straight lines that make angular corner portions at the intersecting positions between the side and bottom surfaces. When the concave portion 443 is formed in a curved shape as shown in FIGS. 1 and 2, the side and bottom surfaces are preferably set to form a Rogowski shape.

Next, an explanation will be given of an outline of a process performed in the plasma processing apparatus 10 configured as described above. At first, a wafer 100 treated as a processing object is placed on the support table 21, and is fixed by the electrostatic chuck mechanism, for example. Then, the inside of the chamber 11 is vacuum-exhausted by a vacuum pump (not shown) connected to the gas exhaust port 14. At this time, since the gas exhaust room 63 and the plasma processing room 61 are connected to each other through the gas exhaust holes 25 formed in the baffle plate 24, the inside of the chamber 11 is vacuum-exhausted as a whole by the vacuum pump connected to the gas exhaust port 14.

Thereafter, when the inside of the chamber 11 reaches a predetermined pressure, a process gas is supplied from a gas supply unit (not shown) into the gas supply room 62. The process gas is supplied from the gas supply room 62 into the plasma processing room 61 through the gas passages 431 of the back plate 43 and the gas passages 445 of the upper electrode 44 in the shower head 41. When the pressure inside the plasma processing room 61 reaches a predetermined pressure, an RF voltage is applied to the support table 21 (lower electrode) while the shower head 41 (upper electrode 44) is grounded, so that plasma 110 is generated inside the plasma processing room 61. Here, a potential gradient is generated between the plasma 110 and the wafer 100 on the lower electrode side due to a self bias caused by the RF voltage, so that ions in the plasma gas are accelerated toward the support table 21, and an anisotropic etching process is thereby performed.

As shown in FIG. 2, near the center of the wafer 100, electric lines of force EL1 extend in the direction perpendicular to the wafer mounting surface. Further, as described above, in the first embodiment, the concave portion 443 is provided on the outer peripheral side of the gas passage arrangement portion 441 of the upper electrode 44, and so the distance between the upper electrode 44 and the lower electrode becomes larger at the concave portion 443. With this arrangement, electric lines of force EL2 at the peripheral edge of the wafer 100 and the outer peripheral area around it can be suppressed from being curved. In other words, the directions of the electric lines of force EL2 can be set in directions almost perpendicular to the wafer mounting surface, even at the peripheral edge of the wafer 100 and the outer peripheral area around it. As a result, it becomes possible to solve non-uniformity of the etching process between the peripheral edge of the wafer 100 and the regions of the wafer 100 other than the peripheral edge. Particularly, if the concave portion 443 is formed in a Rogowski shape by the side and bottom surfaces, this shape is very effective to reduce disturbance of the electric field while suppressing the electric lines of force EL2 from being curved at the peripheral edge of the wafer 100 and the outer peripheral area around it.

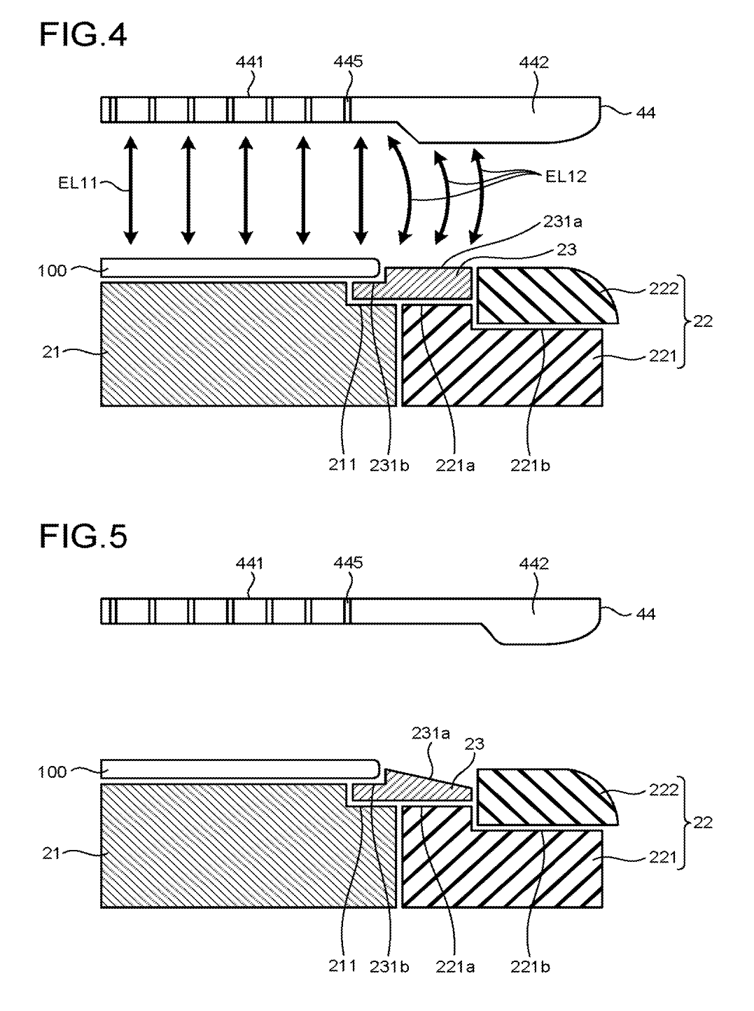

FIG. 4 is a partial sectional view showing a structure including an upper electrode and a lower electrode in a general plasma processing apparatus. The constituent elements corresponding to those described above are denoted by the same reference symbols, and their description will be omitted. According to this general plasma processing apparatus, an upper electrode 44 includes a gas passage arrangement portion 441 and a convex portion 442 provided in the outer peripheral area around the gas passage arrangement portion 441, but it does not include the concave portion 443. The convex portion 442 is arranged opposite to a region extending from near the outer peripheral area around the wafer mounting region to near the peripheral edge of an insulator ring 22. Thus, the convex portion 442 is arranged at a position adjacent to the peripheral edge of the wafer 100.

In the case of this structure, electric lines of force EL11 near the center of the wafer 100 are perpendicular to the wafer mounting surface, but electric lines of force EL12 near the peripheral edge of the wafer 100 and the outer peripheral area around it are curved. This is because the distance between the upper electrode 44 and the lower electrode becomes smaller at a position where the convex portion 442 of the upper electrode 44 is formed. If an etching process is performed under this state, the processing on the wafer 100 becomes uneven. For example, at the regions of the wafer 100 other than its peripheral edge, the formation direction of holes or grooves formed by etching is set in the direction perpendicular to the substrate surface. However, at the peripheral edge of the wafer 100, the formation direction of holes or grooves set in directions inclined from the direction perpendicular to the substrate surface, in accordance with the directions of electric lines of force at respective positions). Consequently, processed shapes become different from each other between positions on the wafer 100.

On the other hand, according to the first embodiment, as shown in FIG. 2, the concave portion 443 is provided on the outer peripheral side of that region upper electrode 44 which opposes the mounting region for the wafer 100, and so the distance between the upper electrode 44 and the lower electrode becomes larger at the peripheral edge of the wafer 100 and the outer peripheral area around it. Consequently, the electric lines of force EL2 at the peripheral edge of the wafer 100 and the outer peripheral area around it are improved from the curved state, as compared with the general case, such that they become closer to perpendicular to the wafer mounting surface. In other words, ions in plasma collide with the upper surface of the wafer 100 by an angle almost perpendicular thereto, at the peripheral edge of the wafer 100, as well as in the regions other than the peripheral edge. Consequently, the processed shape obtained by an etching process at the peripheral edge of the wafer 100 is improved, and thereby it is possible to make the etching process uniform between the peripheral edge of the wafer 100 and the regions other than the peripheral edge.

### Second Embodiment

In the first embodiment, an explanation has been given of a case where the concave portion is provided on the outer peripheral side of that region of the upper electrode which opposes the wafer mounting region. In the second embodiment, an explanation will be given of a case where a shape on the lower electrode side is changed to improve the curves of electric lines of force at the wafer peripheral edge and the cuter peripheral area around it.

FIG. 5 is a partial sectional view schematically showing an example of a structure including an upper electrode and a lower electrode in a plasma processing apparatus according to the second embodiment. According to the second embodiment, an upper electrode 44 includes a gas passage arrangement portion 441 and a convex portion 442. The convex portion 442 is arranged in the region opposing the outer peripheral area around an edge ring 23, and specifically opposing an upper insulator ring 222, in this example. The region described as including the concave portion 443 in the first embodiment, which faces the edge ring 23, is formed with the same thickness as the gas passage arrangement portion 441 and structured by excluding gas passages.

Further, on the premise that the lower surface of the edge ring 23 is flat and the edge ring 23 is mounted on an edge ring mounting portion 221a of a lower insulator ring 221 and on a step portion 211 of a support table the edge ring 23 includes an upper surface portion 231a prepared such that its distance from the upper electrode 44 is increased in a direction from the inner peripheral side toward the outer peripheral side. In other words, the upper surface portion 231a is formed as becoming lower in the direction from the inner peripheral side toward the outer peripheral side. Consequently, the thickness of the edge ring 23 except for a wafer mounting portion 231b is set as being reduced in the direction from the inner peripheral side toward the outer peripheral side. In the example shown in FIG. 5, the upper surface portion 231a of the edge ring 23 has a straight line profile, but it may have a curved line profile. Here, the constituent elements corresponding to those described in the first embodiment are denoted by the same reference symbols, and their description is omitted.

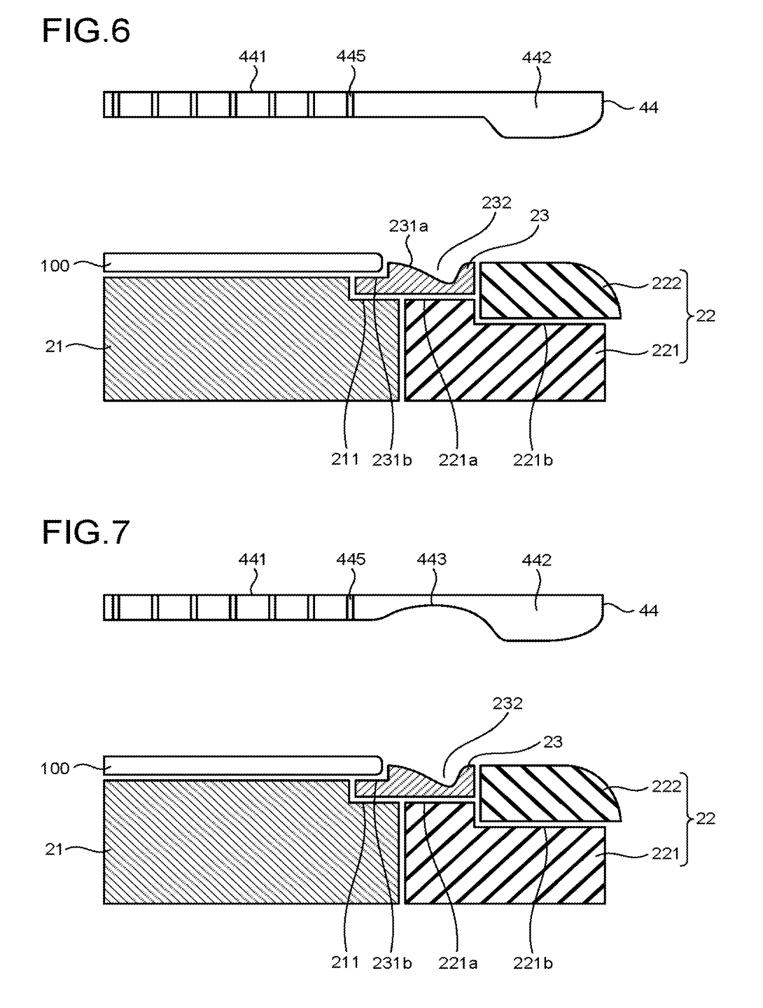

FIG. 6 is a partial sectional view schematically showing another example of a structure including an upper electrode and a lower electrode in a plasma processing apparatus according to the second embodiment. In this example, the structure shown in FIG. 5 is modified such that the thickness of an edge ring 23 on the outer peripheral side is increased, and a concave portion 232 is thereby formed on the upper surface of the edge ring 23. This concave portion 232 may be formed in a curved shape, or may be formed in a shape in which profile lines of a side and bottom surfaces of the concave portion 232 are straight lines that make angular corner portions at the intersecting positions between the side and bottom surfaces. When the concave portion 232 is formed in a curved shape as shown in FIG. 6, the side and bottom surfaces of the concave portion 232 are preferably set to form a Rogowski shape, in order to reduce disturbance of the electric field. Here, the constituent elements corresponding to those described in the first embodiment are denoted by the same reference symbols, and their description is omitted.

According to the second embodiment, the upper electrode 44 is prepared such that it forms a flat structure having the same thickness over the region opposing the wafer mounting region and the region opposing the mounting region for the edge ring 23, and the edge ring 23 is prepared such that the distance of its upper surface portion 231a from the upper electrode 44 is increased in a direction from the inner peripheral side toward the outer peripheral side, at least on the wafer mounting region side (or the support table 21 side) of the edge ring 23. Consequently, it is possible to suppress the electric lines of force from being curved at the peripheral edge of the wafer 100 and the edge ring 23, and thereby to obtain the same effect as the first embodiment.

### Third Embodiment

In order to increase the distance between the upper electrode and the lower electrode, the shape of the upper electrode is changed in the first embodiment, and the shape of the edge ring is changed in the second embodiment. In the third embodiment, an explanation will be given of a case where both of the shape of the upper electrode and the shape of the edge ring are changed.

FIG. 7 is a partial sectional view schematically showing an example of a structure including an upper electrode and a lower electrode in a plasma processing apparatus according to a third embodiment. According to the third embodiment, the structure of the upper electrode 44 according to the first embodiment is combined with the structure of the edge ring 23 shown in FIG. 6 according to the second embodiment. Specifically, the upper electrode 44 includes the gas passage arrangement portion 441 having a predetermined thickness, the convex portion 442 protruding more than the gas passage arrangement portion 441, and the concave portion 443 arranged on the outer peripheral side of the gas passage arrangement portion 441. The edge ring 23 includes the concave portion 232. Further, the concave portion 443 provided on the upper electrode 44 and the concave portion 232 provided on the edge ring are arranged at positions facing each other.

Each of the concave portions 443 and 232 provided on the upper electrode 44 and the edge ring 23 may be formed in a curved shape, or may be formed in a shape in which the profile lines of the side and bottom surfaces of the concave portion 443 or 232 are straight lines that make angular corner portions at the intersecting positions between the side and bottom surfaces. When the concave portion 443 or 232 is formed in a curved shape as shown in FIG. 7, the concave portion is preferably set to form a Rogowski shape, in order to reduce disturbance of the electric field. Here, the constituent elements corresponding to those described in the first and second embodiments are denoted by the same reference symbols, and their description is omitted. Further, the example shown in FIG. 7 employs the edge ring 23 shown in FIG. 6, but it may alternatively employ the edge ring 23 in FIG. 5.

According to the third embodiment, the concave portion 443 is provided on the outer peripheral side of that region of the upper electrode 44 which opposes the mounting region for the wafer 100, and the concave portion 232 is further provided on the edge ring 23 on the lower electrode. Consequently, in the outer peripheral area around the wafer 100, the distance between the upper electrode 44 and the edge ring 23 is further increased as compared with the first and second embodiments. As a result, it is possible to cause the directions of electric lines of force to be further closer to the direction perpendicular to the substrate surface, as compared with the first and second embodiment, and to make the etching process uniform between the peripheral edge of the wafer 100 and the regions other than the peripheral edge.

In the explanation described above, the plasma processing apparatus 10 is exemplified by an RIE apparatus. However, each of the embodiments described above is applicable in general to any processing apparatus or semiconductor manufacturing apparatus, such as an ashing apparatus, CDE (Chemical Dry Etching) apparatus, or CVD (Chemical Vapor Deposition) apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An upper electrode to be arranged opposite to a lower electrode and serving as a shower head in a plasma processing apparatus of a parallel-plate type, comprising:
a concave portion provided on an outer peripheral side of a processing object opposing region configured to face a mounting region for a processing object to be placed on the lower electrode.

2. The upper electrode according to claim 1, further comprising a convex portion provided on an outer peripheral side of the concave portion and configured to protrude toward the lower electrode more than the processing object opposing region.

3. The upper electrode according to claim 1, wherein the concave portion has a Rogowski shape.

4. The upper electrode according to claim 1, further comprising gas passages in the processing object opposing region, the gas passages penetrating the upper electrode in a thickness direction.

5. An edge ring to be arranged around a processing object support member serving as a lower electrode in a plasma processing apparatus of a parallel-plate type,
wherein, in a region of at least a processing object support member side of a surface facing an upper electrode of the plasma processing apparatus, a distance from the upper electrode to the surface increases in a direction from an inner peripheral side of the region toward an outer peripheral side of the region.

6. The edge ring according to claim 5, further comprising a concave portion provided on the surface facing the upper electrode.

7. The edge ring according to claim 6, wherein the concave portion has a Rogowski shape.

8. The edge ring according to claim 5, wherein, in an exposed surface to be exposed to the upper electrode, a distance from the upper electrode to the exposed surface increased in the direction from the inner peripheral side toward the outer peripheral side.

9. The edge ring according to claim 5, further comprising a reverse surface on a reverse side relative to the surface facing the upper electrode, the reverse surface being in parallel with a processing object support surface of the processing object support member and flat.

10. A plasma processing apparatus of a parallel-plate type, comprising:
a chamber;
a processing object support member serving as a lower electrode and configured to hold a processing object in the chamber; and
an upper electrode arranged opposite to the processing object support member and serving as a shower head in the chamber; wherein
an edge ring is arranged around the processing object support member, and
the upper electrode includes a first concave portion provided on an outer peripheral side of a processing object opposing region that faces a mounting region for the processing object of the processing object support member.

11. The plasma processing apparatus according to claim 10, wherein the upper electrode includes a convex portion provided on an outer peripheral side of the first concave portion and protruding toward the lower electrode more than the processing object opposing region.

12. The plasma processing apparatus according to claim 10, wherein the first concave portion has a Rogowski shape.

13. The plasma processing apparatus according to claim 10, wherein a surface of the edge ring facing the upper electrode is in parallel with a processing object support surface of the processing object support member.

14. The plasma processing apparatus according to claim 10, wherein the first concave portion is provided at a position that faces a region where the edge ring is arranged.

15. The plasma processing apparatus according to claim 10, wherein, in a region of at least a processing object support member side of a surface of the edge ring facing the upper electrode, a distance from the upper electrode to the surface of the edge ring increases in a direction from an inner peripheral side of the region toward an outer peripheral side of the region.

16. The plasma processing apparatus according to claim 15, wherein the edge ring includes a second concave portion provided on the surface facing the upper electrode.

17. The plasma processing apparatus according to claim 16, wherein the second concave portion of the edge ring has a Rogowski shape.

18. The plasma processing apparatus according to claim 15, wherein, in an exposed surface of the edge ring to be exposed to the upper electrode, a distance from the upper electrode to the exposed surface is increased in the direction from the inner peripheral side toward the outer peripheral side.

19. The plasma processing apparatus according to claim 10, wherein a thickness of the edge ring is reduced in a direction from an inner peripheral side toward an outer peripheral side.

20. The plasma processing apparatus according to claim 10, wherein the upper electrode includes gas passages in the processing object opposing region, the gas passages penetrating the upper electrode in a thickness direction.
